(19) United States
(12) Patent Application Publication
(10) Pub. No.: US 2021/0223693 A1
(43) Pub. Date: Jul. 22, 2021

(54) PHOTORESIST COMPOSITION, LIQUID DISCHARGE HEAD AND LIQUID DISCHARGE HEAD MANUFACTURING METHOD

(71) Applicant: CANON KABUSHIKI KAISHA, Tokyo (JP)

(72) Inventors: Yohei Hamade, Tokyo (JP); Satoshi Tsutsui, Kanagawa (JP); Isamu Horiuchi, Kanagawa (JP); Kazunari Ishizuka, Shizuoka (JP); Miho Ishii, Kanagawa (JP)

(21) Appl. No.: 17/135,053

(22) Filed: Dec. 28, 2020

(30) Foreign Application Priority Data
Jan. 22, 2020 (JP) 2020-008152

(51) Int. Cl. G03F 7/038; G03F 7/004; G03F 7/32; C08L 63/04; C08G 75/23; C08L 67/02

(52) U.S. Cl. CPC G03F 7/0385; G03F 7/0045; C08L 67/02; C08L 63/04; C08G 75/23; G03F 7/325

(57) ABSTRACT

A photoresist composition is provided, which comprises a cationic polymerization resin, a resin A, a photoacid generator, and a solvent, wherein the resin A comprises at least one resin selected from the group consisting of polyester resins and polyether resins and is soluble in a ketone-based organic solvent.

### BACKGROUND OF THE INVENTION

### Field of the Invention

The present invention relates to a photoresist composition, a liquid discharge head and a method for producing a liquid discharge head.

### Description of the Related Art

Methods of processing photosensitive material films into fine patterns by photolithography techniques are used in the field of advanced devices such as semiconductor elements and display panels. In addition to processability, various functional properties may also be required depending on the application of the fine patterns, and methods have been proposed that impart functionality to the photosensitive material itself. Fine patterns provided with swelling resistance are particularly effective for controlling pattern width and are widely used in fields where line width accuracy is required, as represented by microfluidic devices.

Japanese Patent Application Publication No. 2001-247834 discloses a curable adhesive composition to address problems of warpage and deformation of plastic substrates after adhesion, which are used for optical substrates and electronic substrates. The curable adhesive composition is characterized in that a total resin composition is constituted 40 to 90 wt % of a polyester resin and 10 to 60 wt % of an epoxy resin together with an effective amount of a photocationic polymerization initiator, and an alicyclic epoxy resin constitutes 10 to 90 wt % of the epoxy resin. With this configuration, the curable adhesive composition exhibits adequate coagulation force after curing.

### SUMMARY OF THE INVENTION

The present disclosure is a photoresist composition comprising a cationic polymerization resin, a resin A, a photoacid generator, and a solvent, wherein

the resin A comprises at least one resin selected from the group consisting of polyester resins and polyether resins and is soluble in a ketone-based organic solvent.

The present disclosure is also a method for manufacturing a liquid discharge head provided with a discharge port forming member having a discharge port for discharging a liquid, the method comprising:

a step of forming a discharge port forming layer comprising a photoresist composition;

a step of exposing the discharge port forming layer to light and optically determining a flow path; and

a step of developing the exposed discharge port forming layer, thereby manufacturing a discharge port forming member having a discharge port, wherein

the photoresist composition is a photoresist composition comprising a cationic polymerization resin, a resin A, a photoacid generator, and a solvent, and

the resin A comprises at least one resin selected from the group consisting of polyester resins and polyether resins and is soluble in a ketone-based organic solvent.

The present disclosure is also a liquid discharge head provided with a discharge port forming member having a discharge port for discharging a liquid, wherein

the discharge port forming member comprises a cured product of a photoresist composition,

the photoresist composition is a photoresist composition comprising a cationic polymerization resin, a resin A, a photoacid generator, and a solvent, and

the resin A comprises at least one resin selected from the group consisting of polyester resins and polyether resins and is soluble in a ketone-based organic solvent.

Further features of the present invention will become apparent from the following description of exemplary embodiments with reference to the attached drawings.

### BRIEF DESCRIPTION OF THE DRAWINGS

FIG. 1 is an oblique view of one example of a fine pattern, and

FIGS. 2A, 2B, 2C, and 2D are cross-sectional views showing a method of forming a fine pattern.

### DESCRIPTION OF THE EMBODIMENTS

It is thought that resin materials having swelling resistance generally tend to have increased internal stress. Cracks are therefore likely to occur during development when forming fine patterns, and the desired pattern may not be obtained as a result. Even when cracks do not occur, effects such as deformation of the underlying substrate may occur because the residual stress is high.

On the other hand, when polyester resins are added to photoresist compositions by methods such as those of Japanese Patent Application Publication No. 2001-247834, these resins leave a development residue, and pattern accuracy declines severely. This is thought to be because the added polyester resin fails to melt in the developing solution during the developing step of photolithography, leaving a residue.

These disclosures provide a photoresist composition that achieves both swelling resistance and crack resistance, along with a liquid discharge head using the photoresist composition and a method for manufacturing the liquid discharge head.

When embodiments for carrying out the present invention are specifically illustrated with reference to the drawings, the dimensions, materials and shapes of the constituent members described in these embodiments and the relative placement of these members should be altered appropriately depending on the composition of the members and the various conditions to which the disclosures apply. That is, the scope of the present disclosure is not meant to be limited to the embodiments below.

In the present disclosure, the notations “from XX to YY” and “XX to YY” representing a numerical range denote, unless otherwise stated, a numerical value range that includes the lower limit and the upper limit thereof, as endpoints.

In a case where numerical value ranges are described in stages, the upper limits and the lower limits of the respective numerical value ranges can be combined arbitrarily.

In the explanation below, features having identical functions are denoted in the drawings with identical reference symbols, and a recurrent explanation thereof may be omitted.

The photoresist composition of these disclosures is a photoresist composition comprising a cationic polymerization resin, a resin A, a photoacid generator, and a solvent, wherein the resin A comprises at least one resin selected from the group consisting of polyester resins and polyether resins and is soluble in a ketone-based organic solvent.

A photoresist composition is a composition used in photolithography whose physical properties such as solubility change in response to light, electron beams and the like.

Cationic polymerization resins (cationically polymerizable resins) are used as photoresist compositions because of their patterning properties. From the standpoint of suppressing resin swelling caused by external factors such as liquid contact, the cationic polymerization resin preferably comprises an epoxy resin, and this epoxy resin is more preferably an epoxy resin having an aromatic hydrocarbon group in the main chain. When the epoxy resin has an aromatic hydrocarbon group in the main chain, resin swelling can be suppressed because it is easy to prevent penetration of liquid components into the resin.

The epoxy resin is not particularly limited, and examples include aliphatic epoxy resins, cresol novolac epoxy resins, bisphenol A epoxy resins, bisphenol F epoxy resins, and dicyclopentadiene epoxy resins.

From the standpoint of swelling resistance, the epoxy resin preferably comprises at least one epoxy resin selected from the group consisting of the cresol novolac epoxy resins, bisphenol A epoxy resins, bisphenol F epoxy resins, and dicyclopentadiene epoxy resins.

Examples of commercial products include “N695” (product name, DIC Corp.), “jER 1007” (product name, Mitsubishi Chemical Corp.) and “EHPE-3150” (product name, Daicel Corp.).

The epoxy equivalent weight of the epoxy resin is preferably not more than 2,000, or more preferably not more than 1,000. If the epoxy equivalent weight is not more than 2,000, the crosslinking density does not decline during the curing reaction, and it is possible to prevent declines in the glass transition temperature and adhesiveness of the cured product. The epoxy equivalent weight is measured in accordance with JIS K 7236.

The photoresist composition comprises a resin A. The resin A comprises at least one resin selected from the group consisting of polyester resins and polyether resins and is soluble in a ketone-based organic solvent. A polyester here is a high-molecular-weight compound comprising ester bonds in the molecular main chain structure, while a polyether is a high-molecular-weight compound comprising ether bonds in the molecular main chain structure.

The stress suppression effects (that is, crack resistance) and patterning development properties are considered when selecting the resin A. As discussed below, a ketone-based organic solvent is desirable for the developing solution using during pattern development of the epoxy resin, so a resin A that is soluble in the ketone-based organic solvent is selected.

“Soluble in the ketone-based organic solvent” here means that the amount of the resin A that can be dissolved in 100 mass parts of the ketone-based organic solvent in 5 minutes at room temperature is at least 20 mass parts. The cationic polymerization resin in the photoresist composition is measured in a ketone-based organic solvent comprising the cationic polymerization resin in the same mass ratio as the photoresist composition.

From the standpoint of developing performance, the resin A is preferably amorphous.

The weight-average molecular weight of the resin A is preferably 500 to 100,000, or more preferably 500 to 50,000, or still more preferably 2,000 to 50,000 from the standpoint of the stress suppression effects.

The content of the resin A is preferably 0.01 to 30 mass parts per 100 mass parts (as solids) of the cationic polymerization resin. The content of the resin A is more preferably 0.05 to 25 mass parts, or still more preferably 0.1 to 20 mass parts, or yet more preferably 0.1 to 10 mass parts per 100 mass parts of the cationic polymerization resin (as solids).

When the resin A comprises a polyester resin, the polyester resin preferably has unsaturated bonds from the standpoint of the stress suppression effects. Examples of polyester resins having unsaturated bonds (unsaturated polyester resins) include condensation polymers of polyhydric alcohol components such as diols with acid components comprising unsaturated dibasic acids, and vinyl ester resins that are addition polymers of epoxy resins and (meth)acrylic acids. The resin A preferably comprises an ester resin having unsaturated bonds, such as an unsaturated polyester resin or vinyl ester resin.

The photoacid generator used as a photopolymerization initiator is added as a catalyst for curing the resin. The salts having anionic and cationic structures explained below may be used favorably as photoacid generators.

As for the salts having cationic structures, salts having a sulfonium or iodonium structure with excellent photosensitivity in response to active energy rays such as visible light, ultraviolet rays, electron beams, and X-rays can be used. A sulfonium salt is particularly desirable from the standpoint of thermal stability and storage stability.

As for the salt having anionic structures, a photoacid generator with strong cationic polymerization activity is desirable from the standpoint of ink resistance and mechanical strength, and a phosphorus-based, antimony-based, borate-based, or methide acid-based onium salt is preferred.

Examples of commercial products include “SP-170” (product name, ADEKA), “SP-172” (product name, ADEKA), “CPI-310B” (product name, San-Apro Ltd.) and “WPI-169” (product name, Fuji Film Wako Pure Chemical Corp.).

The content of the photoacid generator in the photoresist composition is preferably 0.1 to 30 mass parts, or more preferably 1 to 10 mass parts per 100 mass parts of the cationic polymerization resin (as solids).

If the content of the photoacid generator is within the above range, the effects of compounding the photoacid generator can be obtained, and bleeding of low-molecular-weight components derived from the photoacid generator out of the cured product of the photoresist composition can be further reduced.

The photoresist composition comprises a solvent. The solvent is not particularly limited as long as it can uniformly disperse the cationic polymerization resin, the resin A and the photoacid generator.

From the standpoint of resin solubility and coating performance, examples include xylene and propylene glycol monomethyl ether acetate.

The solvent may also comprise a non-polar solvent.

When the resin A is hard to dissolve for example, a non-polar solvent such as dimethyl sulfoxide, N, N-dimethyl formamide, N-methyl-2-pyrrolidone, or dimethyl acetamide may be mixed in. The solvent can be used alone or in combination with two or more kinds.

The content of the solvent in the photoresist composition (total content when there are at least two solvents) is preferably 60 to 100 mass parts or more preferably 70 to 90 mass parts per 100 mass parts (as solids) of the cationic polymerization resin.

The method for manufacturing the liquid discharge head is not particularly limited, but the following method is an example.

This is a manufacturing method including a step of forming a discharge port forming layer comprising a photoresist composition, a step of exposing the discharge port forming layer to light and optically determining a flow path, and a step of developing the exposed discharge port forming layer to thereby manufacture a discharge port forming member having a discharge port.

In the step of forming a discharge port forming layer comprising a photoresist composition, for example the photoresist composition can be coated to form a coated film. The coating method is not particularly limited as long as it is a method whereby a uniform film is formed.

A spin coating method or slit coating method may be used for example. The thickness of the coated film is not particularly limited but may be 15 μm to 75 μm for example in the case of a discharge port forming member for an ink jet head.

A step of exposing the resulting discharge port forming layer to light to optically determine the flow path is performed next.

The photoresist composition is preferably a negative composition that becomes less soluble in the developer when the resin composition is cured by light exposure so that the exposed part remains after development.

When using the photoresist composition as described above, a heating step may be performed after the resin composition has been exposed to light at a wavelength that promotes a photocuring reaction of the composition. At this time, it is preferable to adjust the exposure dose in the exposure, taking into account the crack resistance and swelling resistance of a patterned product in which a flow is optically determined.

Specifically, from the standpoint of preventing a loss of crack resistance and swelling resistance due to insufficient curing, the exposure dose for light exposure is preferably at least 1,000 J/m², or at least 2,000 J/m². From the standpoint of preventing chemical cracking caused by poor resolution or excess curing, on the other hand, it is preferably not more than 10,000 J/m², or not more than 8,000 J/m².

Heating is also preferably performed after light exposure. The heating temperature is preferably adjusted to 70° C. to 120° C. for the same reasons given for the exposure dose.

Looking at the cured state of the resin composition before development, the reaction rate of the polymerizable groups of the cationic polymerization resin is preferably at least 50%, or at least 60%, or at least 70%, or more preferably at least 90%. It is also preferably not more than 100%, or not more than 99%, or not more than 98%. The reaction rate of the polymerizable groups of the cationic polymerization resin is, for example, the ring-opening rate of the epoxy groups when an epoxy resin is used as the cationic polymerization resin.

The method of determining the ring-opening rate of the epoxy groups (also called the epoxy group ring-opening rate) when an epoxy resin is used as the cationic polymerization resin is explained here. The epoxy group ring-opening rate represents the ring-opening ratio of the epoxy groups in an epoxy resin composition.

The epoxy group ring-opening rate can be calculated using the peak area derived from epoxy groups based on an absorption spectrum of the epoxy resin composition obtained by Fourier transform infrared spectroscopy (FT-IR). The “peak area derived from epoxy groups” here means the integrated value of a peak derived from the epoxy groups near a wavelength of 910 cm⁻¹ using a line connecting the closest minimum values to the left and right of the peak as a baseline.

Specifically, the epoxy ring-opening rate E (%) is calculated by the following formula given X as the peak area in the absorption spectrum before light exposure and Y as the peak area in the absorption spectrum after light exposure:

E(%)=[(X−Y)/X]×100.

Next, the exposed discharge port forming layer can be developed to manufacture a discharge port forming member having a discharge port. A solvent capable of dissolving the uncured cationic polymerization resin can be suitably used as the developer for development.

Specifically, a ketone-based organic solvent such as propylene glycol monomethyl ether acetate, methyl ethyl ketone, or methyl isobutyl ketone may be used.

Heating treatment (main firing) is preferably performed after development at a temperature of at least 140° C. to promote curing of the resin composition. From the standpoint of preventing cracks due to increased film stress, the film stress of the cured product obtained by the heating treatment (main firing) is preferably not more than 20 MPa.

The method for determining the film stress of the cured product is explained here.

To confirm the stress difference of the cured product itself, a sample is prepared in which the exposure step is a step of full exposure rather than patterning exposure. Immediately after this sample is cured, a laser reflection-type warpage measurement device (FLX-2320-S, manufactured by KLA-Tencor) is used to measure the variation in warpage after film formation, and the calculated internal stress is given as the film stress after curing.

Because a fine pattern formed by the methods of these disclosures has high resolution and mechanical strength, it is suited to fine pattern processing in a variety of advanced device fields and can be used favorably for forming the discharge ports of ink jet heads in particular.

### EXAMPLES

The present disclosure will be explained in detail below with reference to examples and comparative examples, but the disclosure is not limited to the features that are implemented in these examples. The notation “parts” in the examples and comparative examples denote “parts by mass” unless otherwise specified.

### Example 1

### Sample Preparation

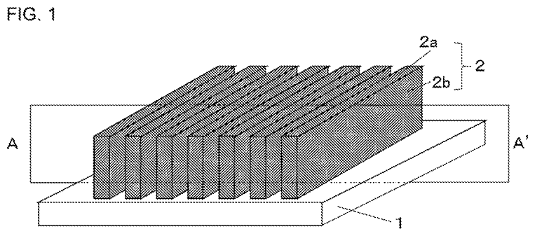

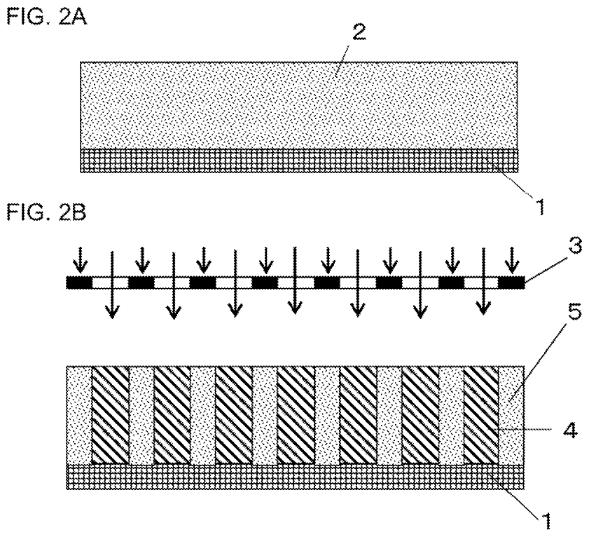

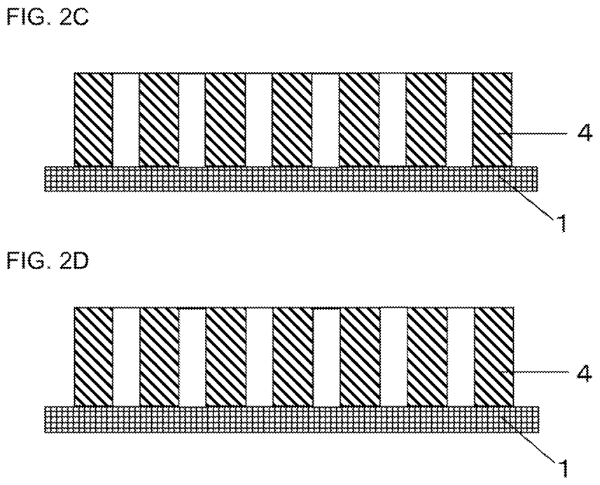

The fine pattern shown in FIG. 1 was prepared. FIG. 2 shows a schematic cross-sectional view taken along the A-A′ line in FIG. 1.

A cationic polymerization resin, resin A, a photoacid generator, and a solvent were first mixed in the composition shown in Table 1 and stirred for 3 days at room temperature to obtain a uniform solution.

Next, as shown in (A) of FIG. 2, the resulting solution was coated to a film thickness of 25 μm on a Si substrate 1 and heat-treated for 9 minutes at 60° C. to form a photoresist composition layer 2.

Using an i-line exposure stepper (Canon Inc.), the photoresist composition layer 2 was then exposed through a photomask 3 to radiant energy with an exposure dose of 4,000 J/m² ((B) of FIG. 2, exposed part 4 and non-exposed part 5). The pattern shape for determining the shape of the fine pattern was set to line/space=10 μm/10 μm. This was then heat-treated for 4 minutes at 90° C. This was then developed with a developer consisting of 6/4 (mass ratio) xylene/methyl isobutyl ketone (MIBK) to form a fine pattern ((C) of FIG. 2). Finally, the photoresist composition layer 2 was completely cured by heat treating it for 1 hour at 200° C. ((D) of FIG. 2).

Evaluation

### Crack Resistance

After steps (C) and (D) of FIG. 2, the resulting fine pattern (top surface 2a and side surface 2b) was observed with an optical microscope (product name: Axio Lab. Al, Carl Zeiss). Crack resistance was evaluated by the following standard.

A: No cracks near the pattern

B: Cracks seen in small part near the pattern, but only at the level of surface cracks

C: Cracks observed near the pattern, extending to a deep part of the pattern

Developing Performance

After step (C) of FIG. 2, the resulting fine pattern was observed with an optical microscope (product name: Axio Lab. Al, Carl Zeiss). Developing performance was evaluated by the following standard.

A: No developing residue occurred B: Developing residue observed in a small part near the pattern, but the size of the residue less than 1 μm

C: Developing residue observed near the pattern, the size of the residue at least 1 μm

Swelling Resistance

As a dimensional accuracy evaluation, the pattern film thickness was measured before testing (after step (D) of FIG. 2) and after testing (after testing by immersion for 3 days at 60° C. in a 5% aqueous solution of 1,2-hexanediol (Fuji Film Wako Pure Chemical Corp.)). The film thickness was measured with a VertScan 2.0 non-contact surface measurement system using optical interferometry (Mitsubishi Chemical Systems Inc.) and evaluated according to the following standard.

The measurement conditions were objective lens=50×, lens barrel=1.0× Body, zoom lens=No Relay, wavelength filter=White, measurement mode=Wave, field size=640×480.

A: Film thickness change after testing less than 5%

B: Film thickness change after testing 5% to 10%

C: Film thickness change after testing more than 10%

Film Stress

A sample was prepared with total exposure in the exposure step (with all other processes being the same as in that step), and the warpage variation after film formation was measured using a laser reflection-type warpage measurement device (FLX-2320-S, KLA-Tencor) immediately after the sample was cured. The calculated internal stress was then given as the film stress of the cured product.

Epoxy Group Ring-Opening Rate

The epoxy group ring-opening rate was calculated by using a Varian 600 UMA FT-IR Microscope (product name, available from Varian) to measure the peak area (near wavelength 910 cm⁻¹) derived from epoxy groups before and after exposure of the sample. The “epoxy group ring-opening rate” measured in the sample before and after exposure matched the “epoxy group ring-opening rate of the epoxy resin contained in the cured product”. The same results were obtained in the examples below.

As shown in Table 2, the fine pattern prepared in Example 1 exhibited good crack resistance, developing performance and swelling resistance.

### Examples 2 to 11

### Sample Preparation

Samples were prepared as in Example 1 except that the cationic polymerization resin, resin A, a photoacid generator, and a solvent were changed as shown in Table 1. Evaluation

The fine patterns prepared in Examples 2 to 11 were evaluated as in Example 1. The results are shown in Table 2.

### Example 12

### Sample Preparation

A sample was prepared as in Example 1 except that the cationic polymerization resin, resin A, a photoacid generator, and a solvent were changed as shown in Table 1.

### Evaluation

The fine pattern prepared in Example 12 was evaluated as in Example 1. The results are shown in Table 2. In comparison with Examples 1 to 11, the pattern height was stable with less variation.

### Example 13

### Sample Preparation

A sample was prepared as in Example 1 except that the exposure dose was changed to 10,000 J/m² in the exposure step for forming the fine pattern.

### Evaluation

The fine pattern prepared in Example 13 was evaluated as in Example 1. The results are shown in Table 2.

### Comparative Example 1

### Sample Preparation

A sample was prepared as in Example 1 except that the cationic polymerization resin, resin A, a photoacid generator, and a solvent were changed as shown in Table 1. Evaluation

The fine pattern prepared in Comparative Example 1 was evaluated as in Example 1. The results are shown in Table 2. Many cracks occurred.

TABLE 1

| | Cationic polymerization resin | | Polyester resin | | | Photoacid generator | | Solvent | | | |
|---|---|---|---|---|---|---|---|---|---|---|---|
| | | Com- | | Weight- | Com- | | Com- | | Com- | | Com- |
| | | pounding | | average | pounding | | pounding | | pounding | | pounding |
| | | ratio | | molecular | ratio | | ratio | | ratio | | ratio |
| | Type | (mass parts) | Type | weight | (mass parts) | Type | (mass parts) | Type | (mass parts) | Type | (mass parts) |
| Example 1 | N695 | 100 | 3600G | 3600 | 5 | 172 | 3 | Xylene | 80 | — | — |
| Example 2 | jER1007 | 100 | 3600G | 3600 | 5 | 172 | 3 | Xylene | 80 | — | — |
| Example 3 | N695 | 100 | 220 | 3000 | 5 | 172 | 3 | Xylene | 80 | — | — |
| Example 4 | N695 | 100 | 5101 | — | 5 | 172 | 3 | Xylene | 80 | — | — |
| Example 5 | N695 | 100 | 219 | 3000 | 5 | 172 | 3 | Xylene | 80 | — | — |
| Example 6 | N695 | 100 | 9940 | 56000 | 5 | 172 | 3 | Xylene | 80 | — | — |
| Example 7 | N695 | 100 | 3600G | 3600 | 20 | 172 | 3 | Xylene | 80 | — | — |
| Example 8 | N695 | 100 | 3600G | 3600 | 0.05 | 172 | 3 | Xylene | 80 | — | — |
| Example 9 | N695 | 100 | 4100G | 4100 | 5 | 169 | 3 | Xylene | 80 | — | — |
| Example 10 | N695 | 100 | 4800G | 4800 | 5 | 172 | 3 | PGMEA | 80 | — | — |
| Example 11 | 3150 | 100 | 3600G | 3600 | 5 | 172 | 3 | Xylene | 70 | NMP | 10 |
| Example 12 | N695 | 100 | 3600G | 3600 | 5 | 172 | 3 | Xylene | 80 | — | — |
| Example 13 | N695 | 100 | 3600G | 3600 | 5 | 172 | 3 | Xylene | 80 | — | — |
| Comparative | N695 | 100 | — | — | — | 172 | 3 | Xylene | 80 | — | — |
| Example 1 | | | | | | | | | | | |

Of the cationic polymerization resins in the table, N695 is a cresol novolac epoxy resin manufactured by DIC Corp., jER 1007 is a bisphenol A epoxy resin manufactured by Mitsubishi Chemical Corp., and 3150 is an alicyclic epoxy resin manufactured by Daicel Corp.

Of the polyester resins in the table, 3600G, 4100G, and 4800G represent Sumikaexcel PES 3600G, 4100G and 4800G (amorphous polyether sulfone resins) manufactured by Sumitomo Chemical Co., Ltd., 220 represents Vylon (trademark) 220 (amorphous polyester resin) manufactured by Toyobo Co., Ltd., 5101 represents UE-5101-L (vinyl ester resin) manufactured by DIC Material Inc., 219 represents Nichigo Polyester TP-219 (amorphous polyester resin) manufactured by Mitsubishi Chemical Corp., and 9940 represents Espel 9940A (amorphous saturated polyester resin) manufactured by Hitachi Chemical Co., Ltd.

Of the photoacid generators in the table, 172 represents ADEKA Optomer SP-172 (sulfonium salt-based energy ray sensitive cationic polymerization initiator) manufactured by ADEKA and 169 represents WPI-169 (iodonium-based photocationic initiator) manufactured by Fuji Film Wako Pure Chemical Corp.

Of the solvents in the table, the xylene was one manufactured by Kanto Chemical Co., Inc., the propylene glycol monomethyl ether acetate (PGMEA) was one manufactured by Showa Denko K.K., and the N-methyl-2-pyrrolidone (NMP) was one manufactured by Mitsubishi Chemical Corp.

TABLE 2

| | Evaluation | | | | |
|---|---|---|---|---|---|
| | Crack | | Swelling | Epoxy ring- | Film |
| | resis- | Developing | resis- | opening rate | stress |
| | tance | performance | tance | (%) | (MPa) |
| Example 1 | A | A | A | 95 | 16 |
| Example 2 | A | A | A | 95 | 16 |
| Example 3 | A | A | A | 95 | 16 |
| Example 4 | A | A | A | 95 | 16 |
| Example 5 | A | A | A | 95 | 16 |
| Example 6 | A | B | A | 95 | 16 |
| Example 7 | A | B | B | 70 | 10 |
| Example 8 | B | A | A | 99 | 19 |
| Example 9 | B | A | B | 50 | 10 |
| Example 10 | A | A | A | 95 | 16 |
| Example 11 | A | A | B | 95 | 16 |
| Example 12 | A | A | A | 95 | 16 |
| Example 13 | B | A | A | 99 | 16 |
| Comparative | C | A | A | 95 | 14 |
| Example 1 | | | | | |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-008152, filed Jan. 22, 2020, which is hereby incorporated by reference herein in its entirety.

What is claimed is:

1. A photoresist composition comprising a cationic polymerization resin, a resin A, a photoacid generator, and a solvent, wherein
the resin A comprises at least one resin selected from the group consisting of polyester resins and polyether resins and is soluble in a ketone-based organic solvent.

2. The photoresist composition according to claim 1, wherein the cationic polymerization resin comprises an epoxy resin.

3. The photoresist composition according to claim 2, wherein the epoxy resin has an aromatic hydrocarbon group in the main chain.

4. The photoresist composition according to claim 2, wherein the epoxy resin comprises at least one epoxy resin selected from the group consisting of cresol novolac epoxy resins, bisphenol A epoxy resins, bisphenol F epoxy resins, and dicyclopentadiene epoxy resins.

5. The photoresist composition according to claim 1, wherein the resin A is amorphous.

6. The photoresist composition according to claim 1, wherein
the resin A is a polyester resin, and
the polyester resin has unsaturated bonds.

7. The photoresist composition according to claim 1, wherein
the resin A is a polyester resin, and
the polyester resin comprises a vinyl ester resin.

8. The photoresist composition according to claim 1, wherein a content of the resin A is 0.1 to 10 mass parts per 100 mass parts of the cationic polymerization resin.

9. The photoresist composition according to claim 1, wherein a weight-average molecular weight of the resin A is 500 to 50,000.

10. The photoresist composition according to claim 1, wherein the solvent comprises a non-polar solvent.

11. The photoresist composition according to claim 1, wherein the solvent comprises at least one solvent selected from the group consisting of dimethyl sulfoxide, N, N-dimethyl formamide, N-methyl-2-pyrrolidone, and dimethyl acetamide.

12. A method for manufacturing a liquid discharge head provided with a discharge port forming member having a discharge port for discharging a liquid, the method comprising:
a step of forming a discharge port forming layer comprising a photoresist composition;
a step of exposing the discharge port forming layer to light and optically determining a flow path; and
a step of developing the exposed discharge port forming layer, thereby manufacturing a discharge port forming member having a discharge port, wherein
the photoresist composition is a photoresist composition comprising a cationic polymerization resin, a resin A, a photoacid generator, and a solvent, and
the resin A comprises at least one resin selected from the group consisting of polyester resins and polyether resins and is soluble in a ketone-based organic solvent.

13. The method for manufacturing a liquid discharge head according to claim 12, wherein an exposure dose for the exposure is at least 2,000 J/m².

14. The method for manufacturing a liquid discharge head according to claim 12, wherein an exposure dose for the exposure is not more than 8,000 J/m².

15. The method for manufacturing a liquid discharge head according to claim 12, wherein a ketone-based organic solvent is used as a developer during the development.

16. The method for manufacturing a liquid discharge head according to claim 12, wherein in the step of manufacturing the discharge port forming member, heat treatment at a temperature of at least 140° C. is performed after development.

17. A liquid discharge head provided with a discharge port forming member having a discharge port for discharging a liquid, wherein
the discharge port forming member comprises a cured product of a photoresist composition,
the photoresist composition is a photoresist composition comprising a cationic polymerization resin, a resin A, a photoacid generator, and a solvent, and
the resin A comprises at least one resin selected from the group consisting of polyester resins and polyether resins and is soluble in a ketone-based organic solvent.

18. The liquid discharge head according to claim 17, wherein
the cationic polymerization resin comprises an epoxy resin, and
an epoxy group ring-opening rate of the epoxy resin contained in the cured product is at least 70%.

19. The liquid discharge head according to claim 17, wherein a film stress of the cured product is not more than 20 MPa.
